(19) United States
(12) Patent Application Publication
(10) Pub. No.: US 2004/0171268 A1
(43) Pub. Date: Sep. 2, 2004

(54) Feed-through manufacturing method and feed-through

(76) Inventor: Mitsuhiro Yuasa, Tokyo (JP)

Correspondence Address: FINNEGAN, HENDERSON, FARABOW, GARRETT & DUNNER, LLP, 1300 I STREET, NW, WASHINGTON, DC, 20005, US

(21) Appl. No.: 10/482,953

(22) PCT Filed: Jun. 26, 2002
(86) PCT No.: PCT/JP02/06435

(30) Foreign Application Priority Data
Jul. 9, 2001 (JP) 2001-207868

(51) Int. Cl. H01L 21/311

(52) U.S. Cl. 438/694

(57) ABSTRACT

A method of producing a feedthrough having a plurality of through conductive parts formed in a substrate is provided. This method includes the steps of: forming a stopper film on one surface of the substrate; forming a plurality of holes that reach the stopper film by etching the substrate; forming a plurality of conductive parts in the plurality of holes; removing the stopper film by etching; and making the top ends of the plurality of conductive parts protrude from the substrate by etching the surface of the substrate from which the stopper film has been removed.

### FIELD OF THE INVENTION

The present invention relates to a method of producing a feedthrough that has through conductive parts formed in a substrate, and also relates to such a feedthrough.

### BACKGROUND OF THE INVENTION

A feedthrough (a conductive through connector or a conductive through connection terminal) having through conductive parts formed in its substrate is normally used to electrically connect two electric (electronic) parts or electric (electronic) devices.

For example, such a feedthrough is used in a semiconductor device test collectively carried out on the integrated circuits of semiconductor devices formed on a semiconductor wafer. Referring now to FIG. 9, this feedthrough will be described below.

A semiconductor wafer 1 is held by a holding plate 2, while a contactor 4 having thin-film probe cards provided with bumps 3 as probe terminals is secured to the holding plate 2 by rings 5. Reference numeral 6 indicates a wiring board, and reference numeral 7 indicates an external connector formed on an outer peripheral part of the wiring board 6. The bumps 3 of the contactor 4 are connected to the external connector 7 via the wiring board 6.

To carry out a burn-in test or the like on a number of semiconductor devices (not shown) formed on the semiconductor wafer 1, the bumps 3 of the contactor 4 are brought into contact with testing electrodes (not shown) formed on the semiconductor devices, and a source voltage or signal voltage is then applied to the bumps 3. Here, the feedthrough is interposed between the bumps 3 and the testing electrodes, so as to prevent abrasion damage to the bumps 3 due to repeated use, and to obtain more reliable conductivity.

Such a feedthrough is produced by drilling through holes in a glass substrate or the like, and then inserting metal conductors in the through holes.

However, since the conventional feedthrough has through holes formed by drilling, it is difficult to form through holes having a diameter as small as several tens of micrometers, for example, and to arrange those through holes at very short intervals of several tens of micrometers.

Because of this, the conventional feedthrough cannot be used as an electric connector part in today's highly integrated electronic devices, and therefore, is not suitable for the above mentioned semiconductor wafer test.

### DISCLOSURE OF THE INVENTION

With the above disadvantages being taken into consideration, the objects of the present invention are to provide a method of producing a feedthrough having conductive parts of very small diameters arranged at very short intervals in a substrate, and to provide such a feedthrough.

The above object of the present invention is achieved by a method of producing a feedthrough having a plurality of through conductive parts formed in a substrate. This method includes the steps of: forming a stopper film on one surface of the substrate; forming a plurality of holes that reach the stopper film by etching the substrate; forming a plurality of conductive parts in the plurality of holes; removing the stopper film by etching; and making the top ends of the plurality of conductive parts protrude from the substrate by etching the surface of the substrate from which the stopper film has been removed.

Here, the materials for the substrate are not specifically limited, but a Si substrate or a quartz substrate is preferable. The materials for the stopper film are not specifically limited either, as long as a material that cannot be affected by etching is employed. For example, a SiO₂ thermal oxide film or the like is preferable as the stopper film. Although the materials for the conductive parts are not specifically limited either, Cu is preferable for the conductive parts.

By this method, a feedthrough having conductive parts with smaller diameters arranged at shorter intervals than those of a feedthrough formed by the conventional drilling technique can be obtained. Also, having uniform protruding lengths, the top ends of the conductive parts of the obtained feedthrough are not uneven but are arranged on a single plane. Accordingly, more reliable electric connection can be achieved by the use of the feedthrough. Furthermore, the protruding lengths of the top ends of the conductive parts of the feedthrough can be adjusted to a desired length with precision.

In this case, it is more preferable if the substrate is made of a conductive material, and the method further includes, between the hole forming step and the conductive part forming step, the step of forming an insulating film on the walls and bottoms of the holes. With this structure, the insulating film serves as a barrier film to prevent current leakage.

In this case, it is even more preferable if the top end of each of the conductive parts is formed into a tapered protrusion in the conductive part protrusion making step. By doing so, the top ends of the conductive parts can be brought into contact with a mating member in a penetrating fashion when the feedthrough is used. If the feedthrough is used in a semiconductor wafer test, the tapered top ends of the conductive parts can break the oxide cover film of the testing electrodes, and ensure reliable electric connection.

In this case, it is even more preferable if the step of forming an oxidation-resistant metal film on the walls and bottoms of the holes formed in the substrate is carried out prior to the conductive part forming step. By carrying out the oxidation-resistant metal film forming step, oxidation damage to be caused to the conductive parts can be reduced.

The materials for the oxidation-resistant metal film are not specifically limited, as long as a material having better oxidation resistance than the material of the conductive parts is employed. For example, materials such as Au are preferable.

It is also preferable if the step of forming an abrasion-resistant metal film on the walls and bottoms of the holes formed in the substrate is carried out prior to the conductive part forming step. When the feedthrough is repeatedly used in a semiconductor wafer testing device or the like, abrasion damage to the conductive parts, which are pressed by parts such as the testing electrodes of a semiconductor wafer, can be reduced by virtue of the abrasion-resistant metal film.

Also, in the hole forming step, the substrate may be over-etched so as to form a widening tapered opening in each of the holes at the side without the stopper film. By doing so, the ends of the conductive parts that are tapered in conformity with the widening tapered openings are engaged with the openings, so that the conductive parts are prevented from falling off the substrate toward the top ends.

A feedthrough in accordance with the present invention is characteristically produced by the above feedthrough producing method.

Thus, a feedthrough that has the effects of the above feedthrough producing method of the present invention can be obtained.

In this case, it is more preferable if the diameter of the top end of each conductive part at the joint with the substrate is 5 to 100 μm, the interval between each two neighboring conductive parts is ½ to 2 times larger than the diameter, and the protruding length of the top end of each conductive part protruding from the substrate is ⅕ to 2 times larger than the interval.

### BRIEF DESCRIPTION OF THE DRAWINGS

FIGS. 1A through 1E illustrate a method of producing a feedthrough in accordance with an embodiment of the present invention, starting from a substrate preparing step shown in FIG. 1A to a hole forming step shown in FIG. 1E;

FIGS. 2A through 2D illustrate the method of producing a feedthrough in accordance with the embodiment of the present invention, starting from a step of embedding a conductive material in the holes shown in FIG. 2A to a conductive part protrusion making step shown in FIG. 2D;

FIG. 3 illustrates a case where the upper ends of the conductive parts also protrude from the substrate in the feedthrough in accordance with the embodiment of the present invention;

FIG. 4 illustrates a first modification;

FIG. 5 illustrates a second modification;

FIG. 6 illustrates a third modification;

FIG. 7 illustrates a fourth modification;

FIG. 8 illustrates a fifth modification; and

FIG. 9 is a schematic section view of a testing device used in conjunction with a method of testing a semiconductor wafer.

### DESCRIPTION OF THE PREFERRED EMBODIMENTS

The following is a description of a feedthrough producing method in accordance with the present invention and a preferred embodiment (hereinafter referred to as the “embodiment”) of a feedthrough to be produced by the method, with reference to the accompanying drawings.

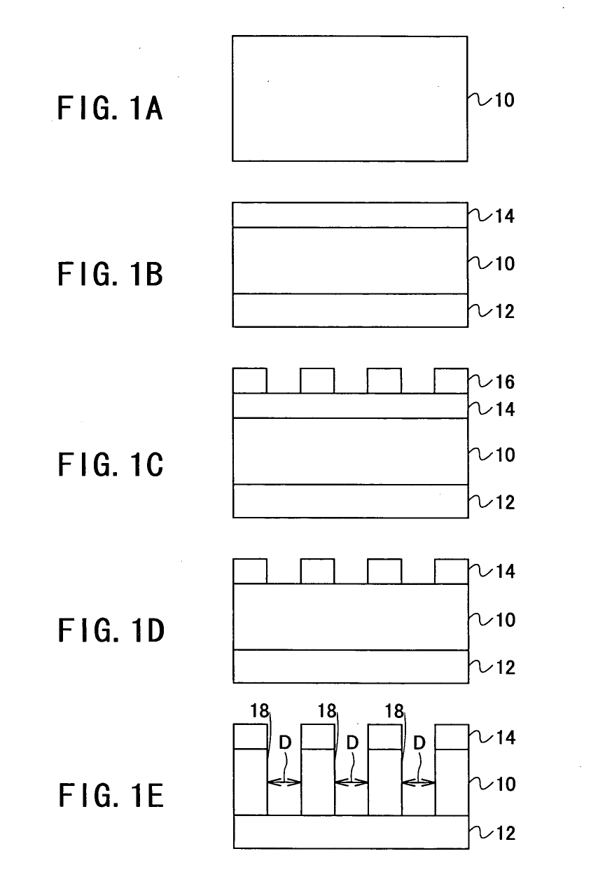

Referring first to FIGS. 1A through 3, a method of producing a feedthrough in accordance with the embodiment will be described.

A Si substrate 10 having a thickness of approximately 700 μm is prepared (FIG. 1A).

The Si substrate 10 is then subjected to thermal oxidation, for example, so that a SiO₂ thermal oxide film 12 having a thickness of 5 μm to 10 μm is formed on the lower surface of the Si substrate 10 (stopper film forming step: FIG. 1B). The SiO₂ thermal oxide film 12 serves as a stopper film in an etching process that will be described later.

Meanwhile, a SiO₂ thermal oxide film 14 having a thickness of 5 μm to 10 μm is formed on the upper surface of the Si substrate 10 in the same manner as the film formation on the lower surface.

Etching is then performed on the Si substrate 10, so as to form holes 18 that reach the upper surface of the SiO₂ thermal oxide film 12 (hole forming step: FIGS. 1C through 1E).

More specifically, a resist film 16 is formed on the SiO₂ thermal oxide film 14, and patterning is then performed on the resist film 16 (FIG. 1C). Using a CF-based gas such as CF₄, C₄F₈, C₅F₈, or C₄F₆, further etching is performed on the SiO₂ thermal oxide film 14, followed by ashing, with the resist film 16 serving as a mask (FIG. 1D). Using a gas such as HBr, Cl₂, or SF₆, etching is performed on the Si substrate 10, with the patterned SiO₂ thermal oxide film 14 serving as a hard mask, so that holes each having a diameter D of 10 μm are formed (FIG. 1E). Here, the SiO₂ thermal oxide film 12 is not etched because of the selectivity, and the holes 18 penetrate only the Si substrate 10.

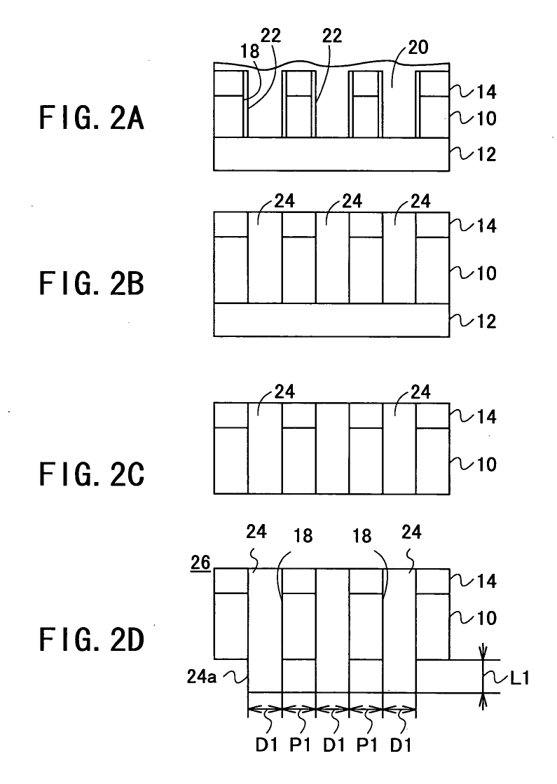

Conductive parts 24 are then formed in the holes 18 (conductive part forming step: FIGS. 2A and 2B).

More specifically, Cu (denoted by reference numeral 20) is employed as a conductive material and embedded in the holes 18 by an appropriate technique such as an electrolytic plating technique or a CVD technique. In a case where a conductive substrate is used, an insulating film 22 made of SiO₂ or the like should preferably be formed on each of the walls of the holes 18 by a CVD technique or the like, as shown in FIG. 2A. These insulating films 22 serve as barrier films to prevent current leakage. If a quartz substrate is employed instead of the Si substrate 10, it is not necessary to form insulating films. It is also preferable to form Ta/TaN films by a CVD technique or the like prior to the embedding of Cu. By doing so, Cu dispersion can be prevented.

After that, the upper layer of Cu is removed by a polishing technique such as a CMP technique, so that the upper surface of the SiO₂ thermal oxide film 14 is exposed. As a result, the conductive parts 24 that are leveled with the upper surface of the SiO₂ thermal oxide film 14 are formed (FIG. 2B). Note that the insulating films 22 shown in FIG. 2A are not shown in FIG. 2B and the following drawings.

The SiO₂ thermal oxide film 12 is then removed by wet etching, dry etching, or the like (stopper film removing step: FIG. 2C).

Lastly, the lower layer of the Si substrate 10 is partially removed by wet etching or the like, so that the top ends 24a of the conductive parts 24 protrude downward from the Si substrate 10 (conductive part protrusion making step: FIG. 2D). At this point, a feedthrough (a conductive through connector or a conductive through connection terminal) 26 that has the top ends 24a of the conductive parts 24 protruding from the Si substrate 10 is completed.

Here, the diameter D1 of the top end 24a (as well as the joint with the substrate) of each conductive part 24, the interval P1 between each two conductive parts 24, and the protruding length L1 of the top end 24a of each conductive part 24 protruding from the Si substrate 10, are all 10 μm.

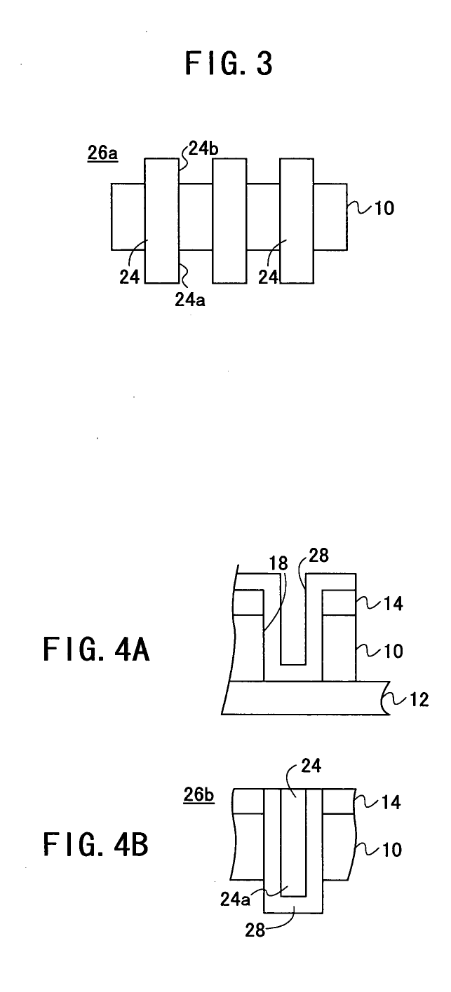

In the stopper film removing step, the SiO₂ thermal oxide film 14 may be removed, as well as the SiO₂ thermal oxide film 12, so that the top end 24b of each conductive part 24 protrudes upward from the Si substrate 10. In this manner, a feedthrough 26a having both ends 24a and 24b of each conductive part 24 protruding from the Si substrate 10 can be formed, as shown in FIG. 3.

By the above method of producing a feedthrough in accordance with the present invention, a feedthrough having conductive parts of smaller diameters arranged at narrower intervals can be obtained, compared with a feedthrough produced by a conventional hole drilling technique. Also, as the top ends of the conductive parts of a feedthrough produced by the above method are formed on the same plane and have the same protruding lengths without irregularities, reliable electric connection can be ensured when the feedthrough is used. The protruding length of the top end of each conductive part in the feedthrough can be adjusted to a desired length. As the feedthrough has the protruding length of the top end of each conductive part and the conductive part interval adjusted under predetermined conditions, the top ends of two neighboring conductive parts are not brought into contact with each other, even if the top ends of the conductive parts are deformed while the feedthrough is being used.

Referring now to FIGS. 4A through 8, modifications of the method of producing a feedthrough in accordance with the embodiment and modifications of the feedthrough will be described.

In a first modification shown in FIGS. 4A and 4B, an oxidation-resistant metal film 28 is formed in the hole forming step. The oxidation-resistant metal film 28 covers the walls and bottoms of the holes 18, as well as the upper surface of the SiO₂ thermal oxide film 14 (FIG. 4A, which corresponds to FIG. 1E). The oxidation-resistant metal film 28 is made of Au, for example, and is formed by a sputtering technique or the like.

After the conductive part forming step, the same procedures as those in the feedthrough producing method in accordance with the embodiment are carried out to obtain a feedthrough 26b having the conductive parts 24, including the top ends 24a, entirely covered with the oxidation-resistant metal film 28 (FIG. 4B).

With the first modification, oxidation damage to be caused to the conductive parts of a feedthrough can be reduced.

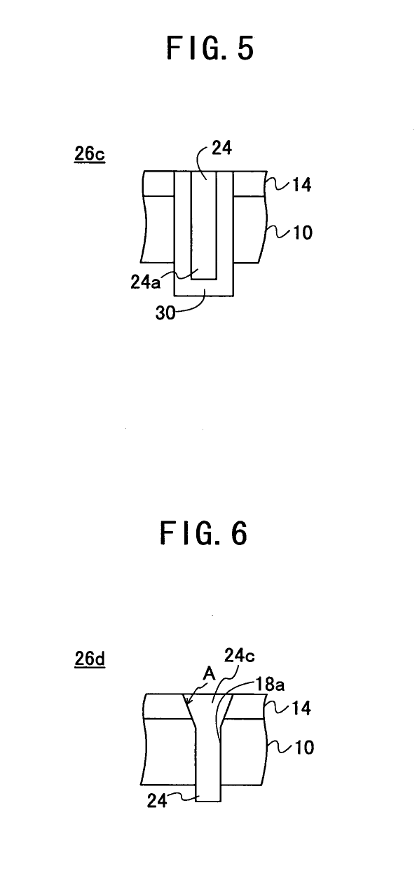

In a second modification shown in FIG. 5, an abrasion-resistant metal film 30 is formed, instead of the oxidation-resistant metal film 28 of the first modification (abrasion-resistant metal film forming step). By doing so, a feedthrough 26c having the conductive parts 24 including the top ends 24a entirely covered with the abrasion-resistant metal film 30 is obtained.

With the second embodiment, abrasion damage to be caused to the conductive parts of a feedthrough can be reduced.

In a third modification shown in FIG. 6, over-etching is performed in the hole forming step (FIG. 1E) of the feedthrough producing method in accordance with the embodiment, so as to form holes 18a each having a tapered opening (indicated by the arrow A in FIG. 6) that widens upward in the upper part of the SiO₂ thermal oxide film 14 and the Si substrate 10. As a result, the upper end 24c of each conductive part 24 is formed in a narrowing tapered shape in conformity with the shape of the corresponding hole 18a. Thus, a feedthrough 26d with the conductive parts 24 each having the upper end 24c engaged with the widening tapered part of the corresponding hole 18a is obtained.

With the third modification, the conductive parts of a feedthrough can be prevented from slipping out from the holes (the Si substrate) toward the top ends (downward in FIG. 6).

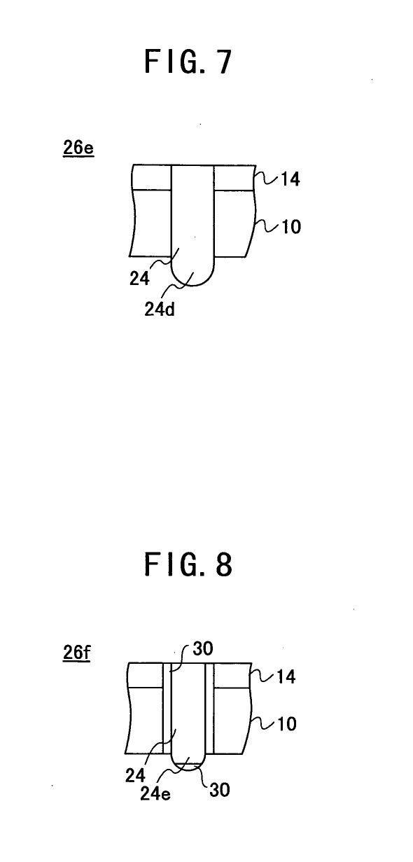

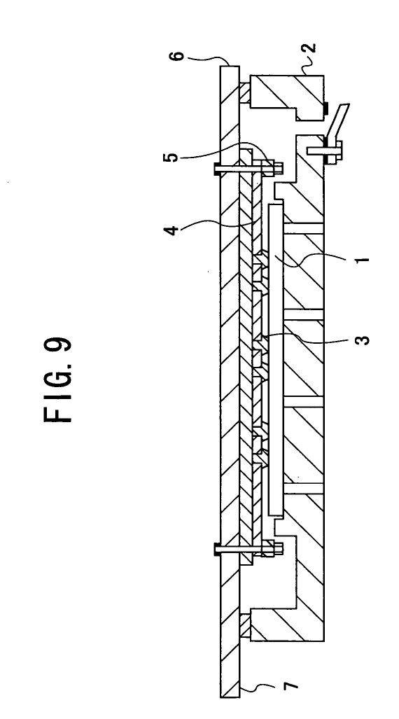

In a fourth modification shown in FIG. 7, reactive ion etching (RIE) is performed in the conductive part protrusion making step (FIG. 2D) of the feedthrough producing method of the embodiment. By doing so, a feedthrough 26e with conductive parts 24 each having a tapered top end 24d is obtained.

With the fourth modification, the top end of each conductive part can be brought into contact with a mating member in a penetrating fashion, when the feedthrough is used.

A fifth modification shown in FIG. 8 is a combination of the second modification and the fourth modification. More specifically, the abrasion-resistant metal film 30 is formed on the wall of each hole 18 in the hole forming step. Reactive ion etching (RIE) is then performed in the conductive part protrusion making step (FIG. 2D), so that the top end 24d of each conductive part 24 is formed in a tapered shape. In this manner, a feedthrough 26f having the tapered top end 24e of each conductive part 24 covered with the abrasion-resistant metal film 30 is obtained.

With the fifth modification, abrasion damage to be caused to the conductive parts when the top ends of the conductive parts are brought into contact with a mating member in a penetrating fashion during the use of the feedthrough is smaller than abrasion damage to be caused to the conductive parts of the fourth modification.

In this case, the oxidation-resistant metal film 28, instead of the abrasion-resistant metal film 30, may be formed on the wall of each hole 18 in the hole forming step. By doing so, excellent electrical conductivity can be obtained when the top ends of the conductive parts are brought into contact with a mating member in a penetrating fashion.

1. A method of producing a feedthrough having a plurality of through conductive parts in a substrate,
the method comprising the steps of:
forming a stopper film on one surface of the substrate;
forming a plurality of holes that reach the stopper film by etching the substrate;
forming a plurality of conductive parts in the plurality of holes;
removing the stopper film by etching; and
making the top ends of the plurality of conductive parts protrude from the substrate by etching the surface of the substrate from which the stopper film has been removed, claim 1 being claimed.

2. The method as claimed in claim 1, wherein the substrate is made of a conductive material,
the method further comprising the step of forming an insulating film on the walls and bottoms of the holes,
the insulating film forming step being carried out between the hole forming step and the conductive part forming step.

3. The method as claimed in claim 1, wherein, in the conductive part protrusion making step, each of the top ends of the conductive parts is formed in a tapered shape so as to protrude from the substrate.

4. The method as claimed in claim 1, further comprising the step of forming an oxidation-resistant metal film on the walls and bottoms of the holes formed in the substrate,
the oxidation-resistant metal film forming step being carried out prior to the conductive part forming step.

5. The method as claimed in claim 1, further comprising the step of forming an abrasion-resistant metal film on the walls and bottoms of the holes formed in the substrate,
the abrasion-resistant metal film forming step being carried out prior to the conductive part forming step.

6. The method as claimed in claim 1, wherein, in the hole forming step, the substrate is over-etched so as to form a widening tapered opening in each of the holes on the side not having the stopper film formed thereon.

7. A feedthrough that can be obtained by the method as claimed in claim 1.

8. The feedthrough as claimed in claim 7, wherein:
the diameter of the top end of each conductive part at the joint with the substrate is 5 μm to 100 μm;
the interval between each two neighboring conductive parts is ½ to 2 times larger than the diameter; and
the protruding length of the top end of each conductive part protruding from the substrate is ⅕ to 2 times larger than the interval.
